(19) United States
(12) Patent Application Publication
(10) Pub. No.: US 2013/0168826 A1
(43) Pub. Date: Jul. 4, 2013

(54) LASER SYSTEM WITH POLARIZED OBLIQUE INCIDENCE ANGLE AND ASSOCIATED METHODS

(71) Applicant: SiOnyx, Inc., Beverly, MA (US)

(72) Inventor: Christopher Vineis, Watertown, MA (US)

(73) Assignee: SiOnyx, Inc., Beverly, MA (US)

(21) Appl. No.: 13/633,030

(22) Filed: Oct. 1, 2012

Related U.S. Application Data
(60) Provisional application No. 61/541,768, filed on Sep. 30, 2011.

(51) Int. Cl. H01L 21/268; H01L 29/06

(52) U.S. Cl. CPC H01L 21/268; H01L 29/06
USPC 257/618; 438/796

(57) ABSTRACT

Novel laser processed semiconductor materials, systems, and methods associated with the manufacture and use of such materials are provided. In one aspect, for example, a method of processing a semiconductor material can include providing a semiconductor material and irradiating a target region of the semiconductor material with a beam of laser radiation to form a laser treated region. The laser radiation is irradiated at an angle of incidence relative to the semiconductor material surface normal of from about 5° to about 89°, and the laser radiation can be at least substantially p-polarized.

### PRIORITY DATA

This application claims the benefit of U.S. Provisional Patent Application Ser. No. 61/541,768, filed on Sep. 30, 2011, which is incorporated herein by reference.

### BACKGROUND

Ultrafast lasers with a pulse duration ranging from 1 femtosecond to hundreds of picoseconds can be used to modify semiconductor surfaces for a variety of applications. One example is to impart surface texture to semiconductor materials such as silicon. Surface texturing is useful to reduce surface reflectance, thereby increasing the amount of light that is transmitted into the material (e.g. silicon). For optoelectronic devices such as solar cells, increased transmittance of light into the device directly improves the efficiency of the device. Surface texturing can also improve light trapping within the material, which can also result in improved efficiency for optoelectronic devices such as solar cells, photodetectors and image sensors.

### SUMMARY

The present disclosure provides novel semiconductor materials and methods associated with the manufacture and use of such materials. In one aspect, for example, a method of processing a semiconductor material can include providing a semiconductor material and irradiating a target region of the semiconductor material with a beam of laser radiation to form a laser treated region. The laser radiation is irradiated at an angle of incidence relative to the semiconductor material surface normal of from about 5° to about 89°, and the laser radiation can be at least substantially p-polarized. In one specific aspect, the angle of incidence can be from about 20° to about 85°. In another specific aspect, the angle of incidence can be from about 40° to about 85°. In a further specific aspect, the angle of incidence can be within about ±15° of the Brewster's angle for the semiconductor material. In yet a further specific aspect, the angle of incidence can be within about ±5° of the Brewster's angle for the semiconductor material.

In one aspect, irradiation of the target region can form surface features on the semiconductor material. While various feature sizes and configurations are contemplated, in one specific aspect the surface features can have a height of from about 1 nm to about 3 microns. In another specific aspect, the surface features can have a height of from about 100 nm to about 1 micron.

Additionally, various laser radiation configurations are contemplated, and any laser configuration capable of generating surface features according to aspects of the present disclosure are considered to be within the present scope. In one aspect, for example, the surface features can be formed using laser pulses having durations of from about 1 femtosecond to about 500 picoseconds.

The present disclosure additionally provides light enhanced semiconductor materials. In one aspect, such a light enhanced semiconductor material can include a semiconductor material and a laser treated region on a surface of the semiconductor material. The laser treated region can having surface features that are oriented at an angle of incidence relative to the semiconductor material surface normal of from about 5° to about 89°. In one specific aspect, the angle of incidence is from about 20° to about 85°. In another specific aspect, the angle of incidence is within about ±15° of the Brewster's angle for the semiconductor material. In a further specific aspect, the angle of incidence is within about ±5° of the Brewster's angle for the semiconductor material.

In another aspect, substantially all of the surface features are oriented at an angle of incidence relative to the semiconductor material surface normal. In another specific aspect, the angles of incidence for substantially all of the surface features are within about 30° of each other. In yet another specific aspect, the angles of incidence for substantially all of the surface features are within about 15° of each other.

### BRIEF DESCRIPTION OF THE DRAWINGS

For a further understanding of the nature and advantage of the present disclosure, reference is being made to the following detailed description of embodiments and in connection with the accompanying drawings, in which:

FIG. 1 illustrates a laser radiation path incident on a substrate at an angle of incidence in relation to the surface normal of the substrate according to one embodiment of the present disclosure;

FIG. 2 shows a reflection coefficient graph of silicon material and light having a specific wavelength and the materials ability to absorb the light, according to one embodiment of the present disclosure;

FIG. 3 is a depiction of a method of processing a semiconductor material in accordance with another embodiment of the present disclosure.

FIG. 4 is a cross-sectional view of a semiconductor structure having surface features in accordance with another embodiment of the present disclosure; and

FIG. 5 illustrates a system for laser processing semiconductor materials according to another embodiment of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “surface modifying,” “surface modification,” and “texturing” can be used interchangeably, and refer to the altering of a surface of a semiconductor material using a texturing technique. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping the material.

As used herein, the term “target region” refers to an area of a semiconductor material that is intended to be surface modified using laser radiation. The target region of a semiconductor material can vary as the surface modifying process progresses. For example, after a first target region is doped or surface modified, a second target region may be selected on the same semiconductor material.

As used herein, the terms “disordered surface” and “textured surface” can be used interchangeably, and refer to a surface having a topology with nano- to micron-sized surface variations or surface features formed by the irradiation of laser pulses. While the characteristics of such a surface can be variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized structures (e.g. about 0.5 μm to about 60 μm). In yet another aspect, the surface can include nano-sized and/or micron-sized structures from about 5 nm to about 500 μm.

As used herein, the term “laser treated region” refers to a portion of a surface of a semiconductor material that has been processed using pulsed laser radiation. The laser treated region can enhance the optical and/or the electrical properties of the semiconductor material.

As used herein, the term “fluence” refers to the amount of energy from a single pulse of laser radiation that passes through a unit area. In other words, “fluence” can be described as the energy density of one laser pulse.

As used herein, the term “detection” refers to the sensing, absorption, and/or collection of electromagnetic radiation.

As used herein, the term “surface normal” or “normal” refers to an optical vector that is perpendicular to the surface.

As used herein, the term “Brewster's angle” or “polarization angle” can be used interchangeably, and refer to an angle of incidence at which light with a particular polarization is perfectly transmitted through a transparent dielectric surface, with no reflection. When unpolarized light is incident at this angle, the light that is reflected from the surface is therefore polarized.

As used herein, the term “translatable” refers to a substrate or optic that is movable in one or more, even combined directions (i.e. x-direction, y-direction and/or z-direction) in relation to a laser light source.

As used herein, the term “substrate” refers to a substance, layer(s) or medium which can underlie, offer support or rigidity to a second substance that can be deposited thereon. For example, a substrate can be a semiconductor silicon wafer used to manufacture integrated circuits.

As used herein, the term “plane of incidence” refers to the plane comprising the laser beam propagation vector (the “optical axis”) and the surface normal at the point of incidence.

As used herein, “polarization” or “polarization state” refers to the state of the laser beam at the point of incidence on the surface with respect to the plane of incidence. A laser bean that is s-polarized (also known as transverse electric polarized to those skilled in the art) is defined herein to mean one that has its electric field orthogonal to the plane of incidence at the point of incidence. A laser beam that is p-polarized (also known as transverse magnetic polarized to those skilled in the art) is defined herein to mean one that has its electric field parallel to the plane of incidence at the point of incidence. Notably, in some aspects the beam need not be 100% of one polarization. In other aspects, the beam can be 100% of one polarization. For example, the p-polarized portion of the beam can be anywhere from 0-100% of the beam energy for a range of angles.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

### THE DISCLOSURE

In forming a textured surface, a laser beam strikes the surface of a target material where some portion of the beam is reflected. The reflected portion does not contribute to the intended process in a useful manner (e.g., surface texturization), and thus represents an overall loss of efficiency for the lasing process. This decreased efficiency has certain implications for laser processes. For example, in certain applications requiring a minimum fluence to be absorbed by the material (e.g., to exceed the melt or ablation thresholds), the incident fluence is higher to account for the reflected light than in the ideal case where 100% of the incident beam is usefully absorbed. In another example, the overall process throughput can be increased as the absorption is increased (i.e., reflectance of the incidence beam is reduced). The beam reflectance can be caused by various physical factors, including initial reflectance of the surface (a function of the material's refractive index and surface topography), as well as steady-state reflectance of the surface upon plasma formation from the lasing process.

With this in mind, methods for processing semiconductor materials and/or wafers with a laser apparatus are provided. More specifically, methods for irradiating a semiconductor material with a laser impinging laser light that is non-perpendicular onto the semiconductor material surface are provided, as well as associated materials, devices, and systems.

It has been discovered that surface texturing can improve the efficiency of a variety of semiconductor devices, particularly optoelectronic devices. For example, etching a light-incident side of a silicon semiconductor optoelectronic device can form surface features that reduce light reflection. Such features can enable a greater proportion of incident light to enter and become absorbed by the silicon material while reducing the amount of incident light that is reflected off the surface.

The reflectance of light at a uniform interface between two homogeneous media is given by Equations I and II:

$$\begin{matrix}\begin{matrix}{R}_{s} = {\vert {r}_{s} \vert}^{2} \\ = {\vert \frac{[ {n}_{i} * cos ( {θ}_{i} ) - {n}_{t} * cos ( {θ}_{t} ) ]}{[ {n}_{i} * cos ( {θ}_{i} ) + {n}_{t} * cos ( {θ}_{t} ) ]} \vert}^{2}\end{matrix} & ( I ) \\ \begin{matrix}{R}_{p} = {\vert {r}_{p} \vert}^{2} \\ = {\vert \frac{[ {n}_{i} * cos ( {θ}_{t} ) - {n}_{t} * cos ( {θ}_{i} ) ]}{[ {n}_{i} * cos ( {θ}_{t} ) + {n}_{t} * cos ( {θ}_{i} ) ]} \vert}^{2}\end{matrix} & ( II )\end{matrix}$$

where Rₛ (Rₚ) is the reflectance amplitude of s (p) polarized light, nᵢ (nₜ) is the complex refractive index of the incident (transmitted) medium, and θᵢ (θₜ) is the incidence angle in the incident (transmitted) medium. The reflectance as a function of incidence angle increases monotonically for s-polarized light (i.e. light with the electric field polarized perpendicular to the plane of incidence) from normal incidence to grazing incidence. In contrast, p-polarized light (i.e. electric field vector in the plane of incidence) has a minimum reflectance somewhere between normal and grazing incidence, at an angle referred to as the Brewster's angle for non-absorbing dielectric media or the pseudo-Brewster's angle for absorbing media.

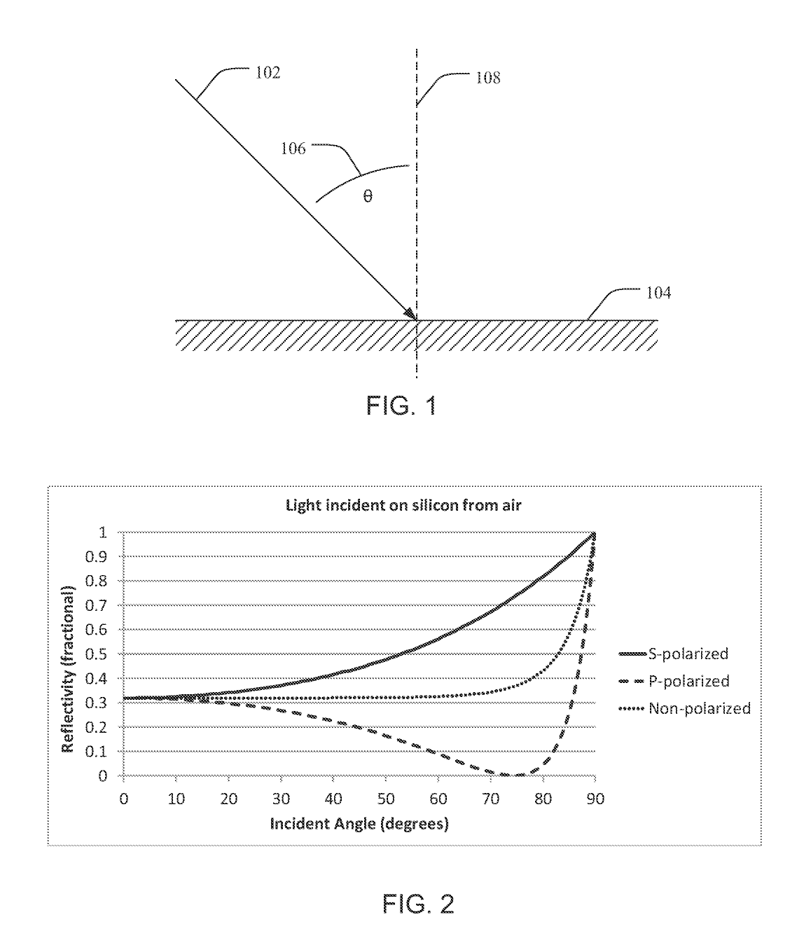

Turning to FIG. 1, for example, a beam 102 of laser radiation is irradiated onto a semiconductor material 104. The beam 102 is directed onto the semiconductor material 104 at an angle of incidence 106 relative to the surface normal 108 of the semiconductor material. If the laser radiation is p-polarized, the angle of incidence 106 is the Brewster's angle at the point of minimum reflectance. It is noted that for clarity of the description, the term “Brewster's angle” will be used to describe both the Brewster's angle for non-absorbing media and the pseudo-Brewster's angle for absorbing media.

FIG. 2 shows a graph showing the reflectance of silicon vs. the incident angle from 0° to 90° of various rays of light having a green wavelength and various polarizations. Notably, the reflectance of an s-polarized green light is highly reflected at incident angles between 40° to 90°. Nonpolarized light increases in reflection for incident angles between 80° to 90°. P-polarized light, however, reduces in reflection for incident angles between 15° and 80°. In other words the silicon material is capable of absorbing more p-polarized green light when the incident angle is between 15° and 80°. Further, p-polarized green light being incident on silicon material at an angle between 5° and 89° is less reflected than s-polarized and non-polarized light at the same angles. It should be noted that p-polarization green light at an incident angle of between about 74° to 78° where the reflectance coefficient is 0 represents the Brewster's Angle.

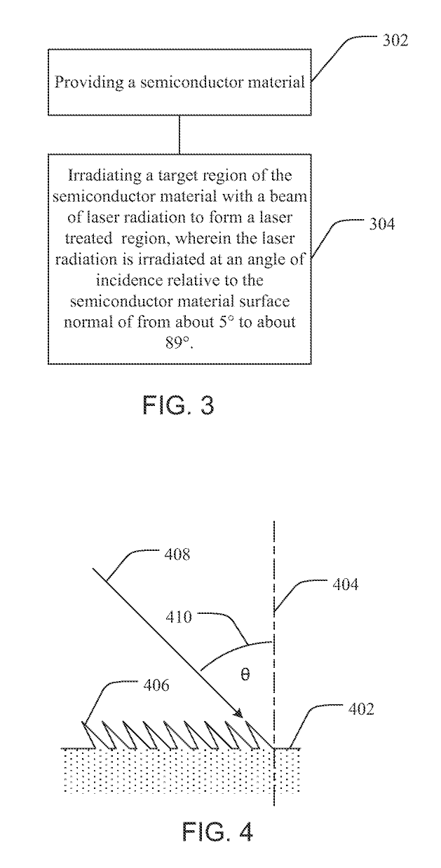

By configuring the laser to reduce the reflected portion of the beam, laser light absorption can be increased during a lasing process, thus improving process efficiency. In one aspect, as is shown in FIG. 3, a method of processing a semiconductor material can include 302 providing a semiconductor material, and 304 irradiating a target region of the semiconductor material with a beam of laser radiation to form a laser treated region. The laser radiation is irradiated at an angle of incidence relative to the semiconductor material surface normal of from about 5° to about 89°. In some aspects, the laser radiation is substantially or completely p-polarized. In other aspects, the laser radiation is substantially or completely p-polarized. In yet other aspects, the laser radiation is a mixture of p-polarization and s-polarization.

Various angles of incidence can be utilized in creating the laser treated region, and specific angles utilized can vary depending on the semiconductor material being used, the characteristics of the laser, desired results of the user, etc. In one specific aspect, for example, the angle of incidence can be from about 20° to about 85° relative to the semiconductor material surface normal. In another specific aspect, the angle of incidence can be from about 40° to about 85° relative to the semiconductor material surface normal. The angle of incidence can also be characterized relative to the Brewster's angle. In one aspect, the angle of incidence can be equal to or substantially equal to the Brewster's angle. In another aspect, the angle of incidence can be within about ±15° of the Brewster's angle for the semiconductor material. In yet another aspect, the angle of incidence can be within about ±5° of the Brewster's angle for the semiconductor material.

The type of laser radiation used to surface modify semiconductor material to create the laser treated region can vary depending on the material and the intended modification. Any laser radiation known in the art can be used with the devices and methods of the present disclosure. There are a number of laser radiation characteristics, however, that can affect the surface modification process and/or the resulting product including, but not limited to, the wavelength of the laser radiation, beam size, beam shape, pulse duration, pulse fluence, pulse frequency, polarization, laser propagation direction relative to the semiconductor material, degree of coherence, etc. Laser pulses can have a central wavelength in a range of about from about 10 nm to about 8 μm, and more specifically from about 200 nm to about 1200 nm. In one aspect, a laser can be configured to provide short-pulsed lasing of the target region of the semiconductor material. For the present disclosure, short-pulsed lasing can include laser pulse durations in the femtosecond, picosecond and/or nanosecond ranges. In one aspect, the pulse duration of the laser radiation can range from about tens of femtoseconds to about hundreds of nanoseconds. In another aspect, laser pulse durations can be from about 50 femtoseconds to about 50 picoseconds. In yet another aspect, laser pulse durations can be from about 50 picoseconds to 900 nanoseconds. In a further aspect, laser pulse widths can be from about 50 to 500 femtoseconds.

The number of laser pulses irradiating a target region can also vary depending on the desired results of the modification. In one aspect, for example, the number of pulses can be from about 1 to about 2000 per unit area. In another aspect, the number of laser pulses can be from about 2 to about 1000 per unit area. Further, the repetition rate or frequency of the pulses can be selected to be in a range of from about 10 Hz to about 10 MHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m². Examples of laser processing have been described in further detail in U.S. Pat. Nos. 7,057,256, 7,354,792 and 7,442,629, which are incorporated herein by reference in their entireties.

In some aspects, the laser treated region can be doped with a dopant species. The dopant species can be present in gas, liquid or solid form. The dopant can be introduced into the semiconductor material during the lasing process, or it can be introduced before or after lasing. A variety of dopant materials are contemplated, and any such material that can be used in the laser treatment process to surface modify a region of the semiconductor material according to aspects of the present disclosure is considered to be within the present scope. It should be noted that the particular dopant utilized can vary depending on the semiconductor material being laser treated, as well as the intended use of the resulting semiconductor material. For example, the selection of potential dopants may differ depending on whether or not tuning of the photosensitive device is desired. A process that does not incorporate any dopant is also contemplated, and the present invention does not require that any dopant be present, incorporated or activated.

A dopant can be either electron donating or hole donating. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials include not only S, but also any material capable being used to dope S into the target region, such as, for example, H₂S, SF₆, SO₂, and the like, including combinations thereof. In one specific aspect, the dopant can be S. Sulfur can be present at an ion dosage level of from about 5×10¹⁴ to about 3×10²⁰ ions/cm². Non-limiting examples of fluorine-containing compounds can include ClF₃, PF₅, F₂SF₆, BF₃, GeF₄, WF₆, SiF₄, HF, CF₄, CHF₃, CH₂F₂, CH₃F, C₂F₆, C₂HF₅, C₃F₈, C₄F_{g}, NF₃, and the like, including combinations thereof. Non-limiting examples of boron-containing compounds can include B(CH₃)₃, BF₃, BCl₃, C₂B₁₀H₁₂, borosilica, B₂H₆, and the like, including combinations thereof. Non-limiting examples of phosphorous-containing compounds can include PF₅, PH₃, POCl₃, P₂O₅, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can include Se, H₂S, SF₆, or mixtures thereof. In yet another aspect, the dopant can be SF₆ and can have a predetermined concentration range of about 5.0×10⁻⁸ mol/cm³ to about 5.0×10⁻⁴ mol/cm³. SF₆ gas is a good carrier for the incorporation of sulfur into the semiconductor material via a laser process without significant adverse effects on the semiconductor material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

A variety of semiconductor materials are contemplated for use with the devices and methods according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The semiconductor material can be of any thickness that allows the desired property or functionality of a resulting semiconductor device, and thus any such thickness of semiconductor material is considered to be within the present scope. The laser treated region can increase the efficiency of a device such that, in some aspects, the semiconductor material can be thinner than has previously been possible. Decreasing the thickness reduces the amount of semiconductor material used to make such a device. It is noted, however, that the present disclosure relates to any thickness of semiconductor material. In one aspect, for example, a semiconductor material such as the semiconductor layer has a thickness of from about 100 nm to about 50 μm. In another aspect, the semiconductor material has a thickness of less than or equal to about 500 μm. In yet another aspect, the semiconductor material has a thickness of from about 1 μm to about 10 μm. In a further aspect, the semiconductor material can have a thickness of from about 5 μm to about 750 μm. In yet a further aspect, the semiconductor material can have a thickness of from about 5 μm to about 100 μm. In another aspect, the semiconductor material can have a thickness that is greater than about 750 μm.

Additionally, various configurations of semiconductor materials are contemplated, and any such material configurations that can be incorporated into a semiconductor device are considered to be within the present scope. In one aspect, for example, the semiconductor material can include monocrystalline materials. In another aspect, the semiconductor material can include multicrystalline materials. In yet another aspect, the semiconductor material can include microcrystalline materials. It is also contemplated that the semiconductor material can include amorphous materials.

The semiconductor material can be coupled to a support substrate to facilitate handling of the device. The support substrate can be of any size, shape, and material capable of supporting the semiconductor material and associated components during manufacture and/or use. The support substrate can be made from various materials, including the semiconductor materials described above, as well as non-semiconductor materials. Non-limiting examples of such materials can include metals, polymeric materials, ceramics, glass, and the like.

The laser treated region can function to diffuse electromagnetic radiation, to redirect electromagnetic radiation, and/or to absorb electromagnetic radiation, thus increasing the quantum efficiency of the device. Laser processing of the target region, and particularly short pulse duration laser processing, can create surface features at the target region of the semiconductor material. Such surface features can, among other things, decrease external reflectance, increase internal reflectance, modify the angle of light propagation inside the semiconductor and increase the optical path length inside the semiconductor. Non-limiting examples of shapes and configurations of surface features include cones, pillars, pyramids, microlenses, quantum dots, inverted features, gratings, protrusions, sphere-like structures, and the like, including combinations thereof. Additionally, surface features can be micron-sized, nano-sized, or a combination thereof. For example, cones, pyramids, protrusions, and the like can have an average height within this range. In one aspect, the average height would be from the base of the feature to the distal tip of the feature. In another aspect, the average height would be from the surface plane upon which the feature was created to the distal tips of the feature. In one specific aspect, a feature (e.g. a cone) can have a height of from about 1 nm to about 3 μm. In another aspect, the height can be from about 50 nm to about 2 μm. In yet another aspect, the height can be from about 100 nm to about 1 μm. Additionally, the lateral dimensions of surface features can also vary. In one aspect, for example, the surface features can have a lateral size near the surface of the target region that is from about 10 nm to about 10 μm. In another aspect, the surface features can have a lateral size near the surface of the target region that is from about 100 nm to about 3 μm. As another example, quantum dots, microlenses, and the like can have an average diameter within the micron-sized and/or nano-sized range.

Laser treated regions according to aspects of the present disclosure can allow a photosensitive device to experience multiple passes of incident electromagnetic radiation within the device, particularly at longer wavelengths (i.e. infrared). Such internal reflection increases the effective optical path length to be greater than the thickness of the semiconductor material. This increase in optical path length increases the quantum efficiency of the device.

In some cases, the electromagnetic radiation absorbing layer can be optionally annealed for a variety of reasons, including dopant activation, dopant diffusion, semiconductor material damage repair, and the like. The semiconductor material can be annealed prior to laser treatment, following laser treatment, during laser treatment, or both prior to and following laser treatment. Annealing can enhance the semiconductive properties of the material, including increasing photoresponse properties. Additionally, annealing can reduce damage created by the lasing process. Although any known annealing process can be beneficial and would be considered to be within the present scope, annealing at lower temperatures can be particularly useful. Such a “low temperature” anneal can greatly enhance the photoconductive gain and external quantum efficiency of devices utilizing such materials. In one aspect, for example, the semiconductor material can be annealed to a temperature of from about 300° C. to about 1200° C. In another aspect, the semiconductor material can be annealed to a temperature of from about 500° C. to about 900° C. In yet another aspect, the semiconductor material can be annealed at a temperature of from about 700° C. to about 800° C. In a further aspect, the semiconductor material can be annealed to a temperature that is less than or equal to about 850° C.

The duration of the annealing procedure can vary according to the specific type of anneal being performed, as well as according to the materials being used. For example, rapid annealing processes can be used, and as such, the duration of the anneal may be shorter as compared to other techniques. Various rapid thermal anneal techniques are known, all of which should be considered to be within the present scope. In one aspect, the semiconductor material can be annealed by a rapid annealing process for a duration of greater than or equal to about 1 μs. In another aspect, the duration of the rapid annealing process can be from about 1 μs to about 1 ms. As another example, a baking or furnace anneal process can be used having durations that may be longer compared to a rapid anneal. In one aspect, for example, the semiconductor material can be annealed by a baking anneal process for a duration of greater than or equal to about 1 ms to several hours.

The present disclosure additionally provides light enhanced semiconductor materials, one example of which is shown in FIG. 4. A portion of semiconductor material 402 is shown having a surface normal 404 and a plurality of surface features 406 formed thereon. The surface features 406 have been formed using a short pulse duration laser. 408 represents the direction of the laser radiation used to form the surface features 406 at an angle of incidence 410. The surface features 406 are thus formed in a direction facing toward the direction from which the laser radiation was delivered. As the angle of incidence 410 of the laser radiation changes, the angle of the surface features 406 will similarly change to reflect the irradiation angle. It should be noted that in some aspects such tilting of the surface features may not be apparent. This may be particularly true in cases where light or minimal texturing is performed.

Accordingly, such a light enhanced semiconductor material can have a laser treated region on a surface of the semiconductor material, where the laser treated region has surface features oriented at an angle of incidence relative to the semiconductor material surface normal of from about 5° to about 89°. In one aspect, substantially all of the surface features can be oriented at an angle of incidence relative to the semiconductor material surface normal. The surface features can be formed in any pattern depending on the desired result. Thus, in some aspects certain patterns of surface features may provide a benefit for the enhancement of the device. In other aspects, a particular pattern may be merely a result of the manufacturing process. For example, the semiconductor material may be rotated during laser processing, and the resulting surface features would have a different orientation depending on the location on the semiconductor. In other aspects, the surface features may be uniform across the semiconductor surface.

In one specific aspect, the angles of incidence for substantially all of the surface features can be within about 30° of each other. In other words, substantially all surface features on the semiconductor material can be within 30° of the same angle of incidence. In another aspect, the angles of incidence for substantially all of the surface features are within about 15° of each other. Similarly, the surface features can be characterized in terms of the Brewster's angle. In one aspect, for example, the angle of incidence for the surface features can be within about ±15° of the Brewster's angle for the semiconductor material. In another aspect, the angle of incidence can be within about ±5° of the Brewster's angle for the semiconductor material.

Systems for irradiating a semiconductor material according to aspects of the present disclosure are also provided. Such a system can include a variety of components, such as a laser source, movable optics, and/or a movable semiconductor wafer carrier. The laser source can emit laser radiation having at least one wavelength in the range of about 200 nm to about 1100 nm. Further the laser source can impinge upon a target region of a semiconductor material at an angle and polarization that can enhance absorption of the laser radiation by the semiconductor substrate as compared to traditional systems. Specifically, a p-polarized laser source can be more readily absorbed, which requires less power to reach the ablation threshold of the semiconductor material than an s-polarized or a non-polarized laser light. The optics of the system can be translatable, though not necessary, such that the optics can be moved or translated to a position that allows the laser light to be directed towards the target region of the semiconductor material at an angle of incidence as has been described. In another aspect, the optics can be stationary while the semiconductor material carrier is movable or translatable such that the laser radiation can be incident on the semiconductor material at an angle that increases absorption. In yet another aspect, both the optics and the wafer can be movable or translatable.

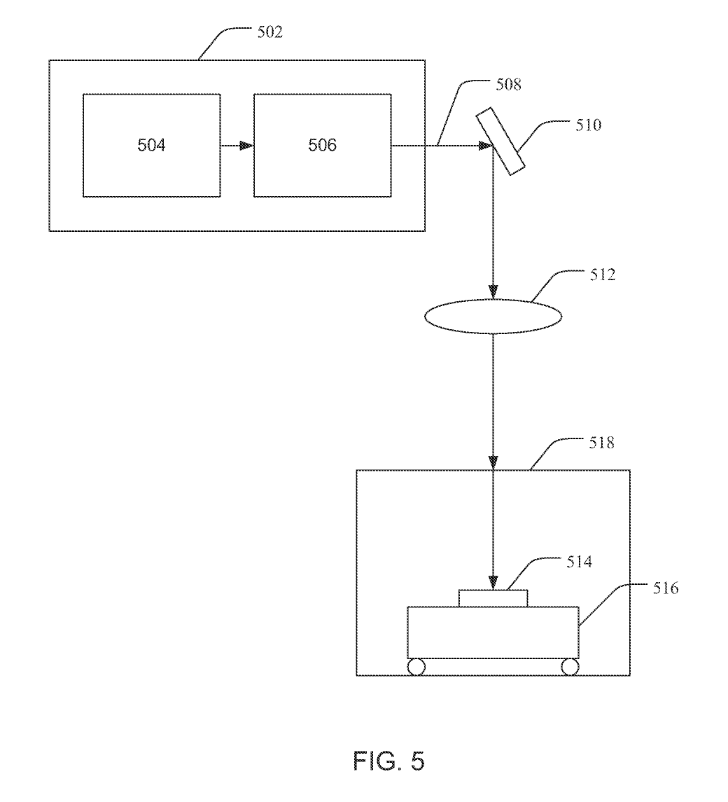

As is shown in FIG. 5, for example, a system is provided that can utilize a p-polarized laser light incident at an oblique angle to minimize reflectance and maximize absorption of the ultra-fast laser beam, thereby increasing the efficiency of the laser processing as have been described. Such a laser processing system can include a laser radiation source 502 having a laser 504 (e.g. a titanium-sapphire laser) and an optional amplifier 506. The system can further include a reflector 510 and at least one optic 512 to direct and focus a beam 508 of laser radiation emitted from the laser source 502. The reflector 510 and the optic 512 can be translatable or movable. It is also contemplated that multiple movable optics, such as a lens, a beam splitter, filters and/or polarizers, as well as the reflector can be translatable or movable. The reflector 510 redirects the pulsed laser beam 508 to the optic 512, which is then focused onto the semiconductor material surface 514. In some aspects, the optic 512 can include a polarizer capable of filtering out light polarized perpendicularly to the axis of the polarizer. This can be useful for obtaining a specific polarization of light, such as a p-polarized light. The system can also include a movable semiconductor material carrier 516. The carrier can be configured to move up to 6 degrees of freedom, i.e. x-direction, y-direction, z-direction and any combinations thereof. Moving up to 6 degrees of freedom can allow the semiconductor material to be moved, tilted or translated such that the laser beam 508 is incident on the semiconductor material surface 514 at an angle of incidence as has been descried herein. Optionally, a lasing chamber or enclosure 518 can also be included in the present system. The chamber can be configured to contain a gas and a dopant gas such that dopant can be introduced into the semiconductor substrate during lasing.

In another aspect, an automated system can include a static wafer that is loaded and unloaded onto a platform, where a laser beam is rastered across the surface in some fashion at the oblique incidence angle. In a further aspect, an automated system can move the wafer either in a continuous or step motion where a static laser beam impinges the surface at an oblique angle. Additionally, it is contemplated that a system can combine a movable laser beam with a movable wafer system.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of processing a semiconductor material, comprising:
providing a semiconductor material;
irradiating a target region of the semiconductor material with a beam of laser radiation to form a laser treated region, wherein the laser radiation is irradiated at an angle of incidence relative to the semiconductor material surface normal of from about 5° to about 89°, and wherein the laser radiation is substantially p-polarized.

2. The method of claim 1, wherein the angle of incidence is from about 20° to about 85°.

3. The method of claim 1, wherein the angle of incidence is from about 40° to about 85°.

4. The method of claim 1, wherein the angle of incidence is within about ±15° of the Brewster's angle for the semiconductor material.

5. The method of claim 1, wherein the angle of incidence is within about ±5° of the Brewster's angle for the semiconductor material.

6. The method of claim 1, wherein irradiating the target region forms surface features on the semiconductor material.

7. The method of claim 6, wherein the surface features have a height of from about 1 nm to about 3 microns.

8. The method of claim 6, wherein the surface features have a height of from about 100 nm to about 1 micron.

9. The method of claim 6, wherein the surface features are formed using laser pulses having a duration of from about 1 femtosecond to about 500 picoseconds.

10. The method of claim 1, wherein the laser treated region is heat annealed subsequent to irradiating with the laser radiation.

11. A light enhanced semiconductor material, comprising:
a semiconductor material;
a laser treated region on a surface of the semiconductor material, the laser treated region having surface features oriented at an angle of incidence relative to the semiconductor material surface normal of from about 5° to about 89°.

12. The material of claim 11, wherein substantially all of the surface features are oriented at an angle of incidence relative to the semiconductor material surface normal.

13. The material of claim 12, wherein the angles of incidence for substantially all of the surface features are within about 30° of each other.

14. The material of claim 12, wherein the angles of incidence for substantially all of the surface features are within about 15° of each other.

15. The material of claim 11, wherein the angle of incidence is from about 20° to about 85°.

16. The material of claim 11, wherein the angle of incidence is within about ±15° of the Brewster's angle for the semiconductor material.

17. The material of claim 11, wherein the angle of incidence is within about ±5° of the Brewster's angle for the semiconductor material.

18. The material of claim 11, wherein the semiconductor material is comprised of silicon.

19. The material of claim 11, wherein the semiconductor material is selected from the group consisting of group III-V, group II-VI, and group I-III-VI.

20. The material of claim 11, wherein the surface features have a height of from about 1 nm to about 3 microns.

21. The material of claim 11, wherein the surface features have a height of from about 100 nm to about 1 micron.
